(19) United States
(12) Patent Application Publication
(10) Pub. No.: US 2017/0256751 A1
(43) Pub. Date: Sep. 7, 2017

(54) DISPLAY PANEL, METHOD OF MANUFACTURING THE SAME AND DISPLAY DEVICE

(71) Applicant: BOE TECHNOLOGY GROUP CO., LTD., Beijing (CN)

(72) Inventor: Yanliu SUN, Beijing (CN)

(21) Appl. No.: 15/233,161

(22) Filed: Aug. 10, 2016

(30) Foreign Application Priority Data
Mar. 7, 2016 (CN) 201610127607.5

(51) Int. Cl. H01L 51/52; H01L 51/56; H01L 27/32

(52) U.S. Cl. CPC H01L 51/5281; H01L 51/5253; H01L 51/5218; H01L 27/3246; H01L 51/56; H01L 2227/323

(57) ABSTRACT

A display panel and a manufacturing method thereof and a display device are disclosed. The display panel includes a light emitting layer and a light filter pattern corresponding to the light emitting layers. The light filter pattern is arranged on the corresponding light emitting layer, the light filter pattern has a specific transmission spectrum; the light filter pattern is configured for filtering out the light corresponding to a spectrum outside the specific transmission spectrum and transmitting the light corresponding to the specific transmission spectrum. The display panel can have a decreased reflectivity of the ambient light and an increased contrast ratio.

### TECHNICAL FIELD

Embodiments of the present disclosure relate to a display panel and a manufacturing method thereof, and a display device.

### BACKGROUND

With the development of display technologies, the application of organic light-emitting diode (OLED) display panels has become increasingly widespread. The outdoor contrast ratio characteristics of OLED display panel have attracts more and more attention among research institutes and consumers.

The ambient light may directly irradiate on and reflects by the electrode of the OLED device in an OLED display panel, the reflectivity of the ambient light by the OLED display panel is relatively high, and therefore the contrast ratio of the OLED display panel is accordingly decreased.

### SUMMARY

An embodiment of the present disclosure provides a display panel, comprising: a light emitting layer and a light filter pattern corresponding to the light emitting layer. The light filter pattern is located at a light-emitting side of the light emitting layer, and the light filter pattern has a specific transmission spectrum; the light filter pattern is configured for filtering out light corresponding to a spectrum outside the specific transmission spectrum and transmitting light corresponding to the specific transmission spectrum.

Another embodiment of the present disclosure provides a display device, comprising the above display panel.

Further another embodiment of the present disclosure provides a method of manufacturing a display panel, comprising: forming a light emitting layer; and forming a light filter pattern, wherein the light filter pattern is located at a light-emitting side of the light emitting layer, the light filter pattern has a specific transmission spectrum, and the light filter pattern is configured for filtering out light corresponding to a spectrum outside the specific transmission spectrum and transmitting the light corresponding to the specific transmission spectrum.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic diagram of a structure of a display panel provided by a first embodiment of the present disclosure.

FIG. 2 is a schematic diagram of the specific transmission spectrum of the light filter pattern and the emission spectrum of the light emitting layer illustrated in FIG. 1.

FIG. 3 is a flow chart of a method of manufacturing a display panel provided by a third embodiment of the present disclosure.

FIG. 4a is a schematic diagram of forming the first electrode in the third embodiment of the present disclosure.

FIG. 4b is a schematic diagram of forming the pixel defining layer in the third embodiment of the present disclosure.

FIG. 4c is a schematic diagram of forming the light emitting layer in the third embodiment of the present disclosure.

FIG. 4d is a schematic diagram of forming the encapsulation layer in the third embodiment of the present disclosure.

FIG. 5 is a schematic diagram of a structure of a modification to the display panel provided by the first embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

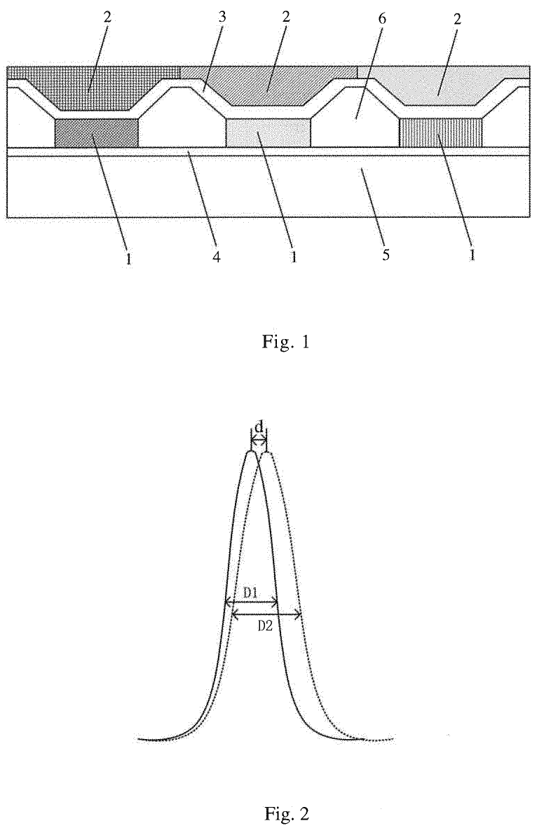

FIG. 1 is a schematic diagram of a structure of a display panel provided by the first embodiment of the present disclosure. As illustrated in the FIG. 1, the display panel comprises: a plurality of light emitting layers 1 and a plurality of light filter patterns 2 respectively corresponding to the light emitting layers 1, the light filter patterns 2 are located on the light-emitting side of the corresponding light emitting layers 1, the light filter patterns 2 each have a specific transmission spectrum; the light filter patterns 2 are provided for filtering out the light corresponding to the spectrum outside the specific transmission spectrum and transmitting the light corresponding to the specific transmission spectrum.

In the present embodiment, for instance, the light emitting layers 1 can comprise a red light emitting layer R, a green light emitting layer G, or a blue light emitting layer B. In FIG. 1, the light emitting layers 1 are a red light emitting layer R, a green light emitting layer G and a blue light emitting layer B which are arranged successively from left to right.

In the present embodiment, each of the light emitting layers 1 can correspond to one light filter pattern 2. To assist corresponding light emitting layer 1, each of the light filter patterns 2 has a respective specific transmission spectrum. Because the light filter pattern 2 has a specific transmission spectrum, the light filter pattern 2 can filter out the light corresponding to the spectrum outside the specific transmission spectrum and therefore block the light corresponding to the spectrum outside the specific transmission spectrum from transmitting through the light filter pattern 2 when the light irradiates on the light filter pattern 2.

In the present embodiment, the material of the light filter pattern 2 may be an inorganic material or an organic material. If the material of the light filter pattern 2 is an inorganic material, the material of the light filter pattern 2 is preferably an inorganic pigment; if the material of the light filter pattern 2 is an organic material, the material of the light filter pattern 2 is preferably an organic pigment.

In the present embodiment, the display panel may further comprise an encapsulation layer 3, the encapsulation layer 3 is provided on the light emitting layers 1, the light filter patterns 2 are arranged on the encapsulation layer 3. For instance, the material of the encapsulation layer 3 is tetrafluoroethylene (TFE).

In the present embodiment, the display panel may further comprise a first electrode 4, which is arranged below the light emitting layers 1. For instance, the first electrode 4 can be an anode, which is a reflective anode, and the reflective anode has a relatively high reflectivity. Therefore, the first electrode 4 can be used for reflecting incident light.

In the present embodiment, the display panel may further comprise a driving backplane 5; the driving backplane 5 is arranged below the light emitting layers 1. For instance, the driving backplane 5 is arranged below the first electrode 4. For instance, the backplane 5 is a thin film transistor (TFT) backplane, in which TFTs are provided as switching elements or driving elements. For instance, the driving backplane 5 comprises a pixel array, which comprises a plurality of pixel units arranged in an array, and each pixel unit comprises TFTs as switching elements and driving components.

In the present embodiment, the display panel may further comprise a pixel defining layer (PDL) 6; the light emitting layers 1 are arranged in the pixel defining layer 6. The pixel defining layer 6 on both sides of a light emitting layer 1 form a groove above the light emitting layer 1, and the light filter pattern 2 corresponding to this light emitting layer I is located in the groove. For instance, if the encapsulation layer 3 is provided, part of encapsulation layer 3 is located in the groove, and the corresponding light filter pattern 2 is arranged on the encapsulation layer 3 while located in the groove. Because the light filter pattern 2 is located in the groove formed by pixel defining layer 6, the thickness of the display panel is not increased, which is beneficial to the bending and curling of the display panel in the case of a flexible display panel.

In the present embodiment, the display panel may further comprise second electrodes, each of the second electrodes is arranged between the light emitting layer 1 corresponding to this second electrode and the encapsulation layer 3, i.e., the second electrode is arranged on the light emitting layer 1 corresponding to it, and the encapsulation layer 3 is arranged on the second electrode. The second electrode can be a cathode. Please refer to the second electrode 10 as illustrated in FIG. 5.

When the ambient light is irradiated on a light filter pattern 2, the light filter pattern 2 can filter out the light corresponding to the spectrum outside the specific transmission spectrum from the ambient light; the light corresponding to the spectrum outside the specific transmission spectrum, which is filter out from the ambient light, cannot transmitted through the light filter pattern 2; therefore, part of the light is filter out from the ambient light. Meanwhile, the light filter pattern 2 can transmit part of the ambient light corresponding to the specific transmission spectrum, and enable the part of the ambient light corresponding to the specific transmission spectrum to pass through the light filter pattern 2. The part of the ambient light transmitted through the light filter pattern 2 irradiates on the first electrode 4, the first electrode 4 will reflect the incident light. Because part of the ambient light is filter out by the light filter pattern 2, the amount of the ambient light which is irradiated on the first electrode 4 is decreased, and the reflectivity for the ambient light is accordingly decreased.

Assume the reflectivity of the ambient light is 1 when the display panel do not have the light filter patterns; for the display panel with the light filter patterns 2 in the present embodiment, the reflectivity of the region corresponding to the red light emitting layer R is 0.056, the reflectivity of the region corresponding to the green light emitting layer G is 0.065, and the reflectivity of the region corresponding to the blue light emitting layer B is 0.036; therefore, the reflectivity of the ambient light by the overall display panel is 0.157, which is reduced by 85% compared with the display panel without the light filter pattern.

When the light emitted by the light emitting layers 1 irradiates on the light filter patterns 2, the light filter patterns 2 filter the light emitted by the light emitting layers 1, i.e., the light filter patterns 2 can filter out the light corresponding to the spectrum outside the specific transmission spectrums from the light emitted by the light emitting layers 1, and the light filter patterns 2 can also transmit part of the light emitted by the light emitting layers 1 corresponding to the specific transmission spectrums. Therefore, in order to make the light emitted by the light emitting layers 1 transmit through the light filter patterns 2 with minimum loss, it is necessary to set the specific transmission spectrums of the light filter patterns 2 and the emission spectrums of the light emitting layers 1.

FIG. 2 is a schematic diagram of the specific transmission spectrum of a light filter pattern as illustrated in FIG. 1 and the emission spectrum of the light emitting layer corresponding to the light filter pattern. As illustrated in FIG. 2, FIG. 2 shows two lines, the solid line represents the specific transmission spectrum of the light filter pattern 2; the dash line represents the emission spectrum of the light emitting layer 1. In the present embodiment, the absolute value of the difference “d” between the peak value of the specific transmission spectrum of the light filter pattern 2 and the peak value of the emission spectrum of the corresponding light emitting layer 1 is no more than a first set value; the first set value is preferably 5 nm. Therefore, when the relationship between the specific transmission spectrum of the light filter pattern 2 and the emission spectrum of the light emitting layer 1 meet above peak value requirement, it is means the specific transmission spectrum of the light filter pattern 2 and the emission spectrum of the light emitting layer 1 is relatively close to each other, and the light emit by the light emitting layer 1 can transmit through the light filter pattern 2 with minimum loss. In FIG. 2, the horizontal axis represents wavelength, the vertical axis represents quantity of emission, and the peak value represents the peak value of wavelength.

As illustrated in FIG. 2, furthermore, the absolute value of the difference between the FWHM (full width at half maximum) value D1 of the specific transmission spectrum of the light filter pattern 2 and the FWHM value D2 of the emission spectrum of the corresponding light emitting layer 1 is no more than a second set value, and the second set value is preferably 40 nm. Therefore, when the relationship between the specific transmission spectrum of the light filter pattern 2 and the emission spectrum of the corresponding light emitting layer 1 meet above peak value and FWHM requirements, it is means that the specific transmission spectrum of the light filter pattern 2 and the emission spectrum of the light emitting layer 1 is even closer, and the light emitted by the light emitting layer 1 can transmit through the light filter pattern 2 with minimum loss. Above mentioned FWHM represents the FWHM of the wavelength of the horizontal axis.

Preferably, the difference between the peak value of the specific transmission spectrum of the light filter pattern 2 and the peak value of the emission spectrum of the corresponding light emitting layer 1 is close to zero or zero, the difference between the FWHM value D1 of the specific transmission spectrum of the light filter pattern 2 and the FWHM value D2 of the emission spectrum of the corresponding light emitting layer 1 is close to zero or zero. In this case, the specific transmission spectrum of the light filter pattern 2 and the emission spectrum of the corresponding light emitting layer 1 is completely overlapped, which is not illustrated in the drawings. Therefore, when the relationship between the specific transmission spectrum of the light filter pattern 2 and the emission spectrum of the corresponding light emitting layer 1 meet above peak value and FWHM requirements, it is means the light filter pattern 2 and the emission spectrum of the light emitting layer 1 are the same, and the light emitted by the light emitting layer 1 can almost totally transmit through the light filter pattern 2 without any loss, thus the luminous efficiency is accordingly increased.

In the present embodiment, the specific transmission spectrum of the light filter pattern 2 is set according to the emission spectrum of the light emitting layer 1. Because of the micro-cavity effect of the luminescent device, in which the light emitting layer 1 is provided, the emission spectrum of the light emitting layer 1 is relatively narrow, and in turn the specific transmission spectrum of the light filter pattern 2 is relatively narrow too; therefore, the light filter pattern 2 can filter out most of the ambient light. The luminescent device may comprise a first electrode, a light emitting layer, and a second electrode, which may be sequentially stacked.

In the present embodiment, preferably, the display panel may be an OLED display panel.

For the display panel provided by the present embodiment, a light filter pattern is located at the light-emitting side of the light emitting layer corresponding to this light filter pattern, and the light filter pattern has a specific transmission spectrum; the light filter pattern is used for filtering out the light corresponding to the spectrum outside the specific transmission spectrum and transmit the light corresponding to the specific transmission spectrum; the light filter pattern can filter out part of the light, thus the reflectivity of the ambient light irradiated on the display panel is decreased and the contrast ratio of the display panel is increased.

The second embodiment of the present disclosure provides a display device, the display device comprises a display panel, which adopts anyone of the display panels provided by the embodiment 1; the detail description of the display panel can refer to the embodiment 1.

The display device provided by the present embodiment, a light filter pattern is located at the light-emitting side of the light emitting layer corresponding to the light filter pattern, the light filter pattern has a specific transmission spectrum; the light filter pattern is used for filtering out the light corresponding to the spectrum outside the specific transmission spectrum and transmit the light corresponding to the specific transmission spectrum; the light filter pattern can filter out part of the light, thus the reflectivity of ambient light irradiated on the display panel is decreased and the contrast ratio of the display panel is increased.

The third embodiment of the present disclosure provides a method of manufacturing a display panel. The method comprises: forming a light emitting layer and forming a light filter pattern. The light filter pattern is located at the light-emitting side of the light emitting layer, the light filter pattern has a specific transmission spectrum; the light filter pattern is used for filter out the light corresponding to the spectrum outside the specific transmission spectrum and transmit the light corresponding to the specific transmission spectrum. For instance, the light filter pattern can be formed by a vapor deposition process or a printing process.

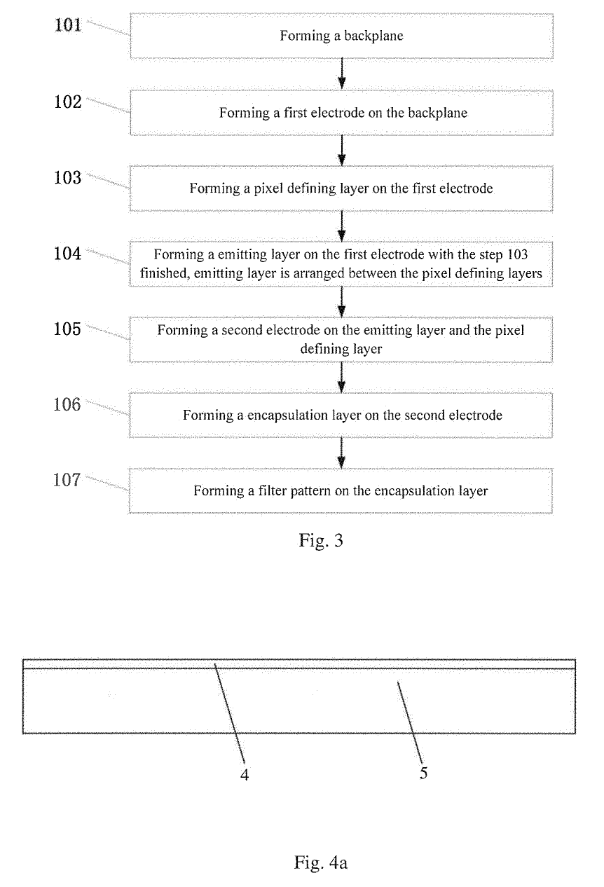

In the following, the method of manufacturing a display panel provided by the third embodiment will be described in detail with reference to an example. FIG. 3 is a flow chart of a method of manufacturing a display panel provided by the third embodiment of the present disclosure; as illustrated in FIG. 3, the method comprises the following operations.

Step 101: providing a driving backplane.

In the present embodiment, the driving backplane may be a TFT backplane, comprising TFTs as switching elements or driving elements. The TFT backplane is an active driving backplane. The driving backplane may be formed by way of semiconductor manufacturing processes.

Step 102: forming a first electrode on the backplane.

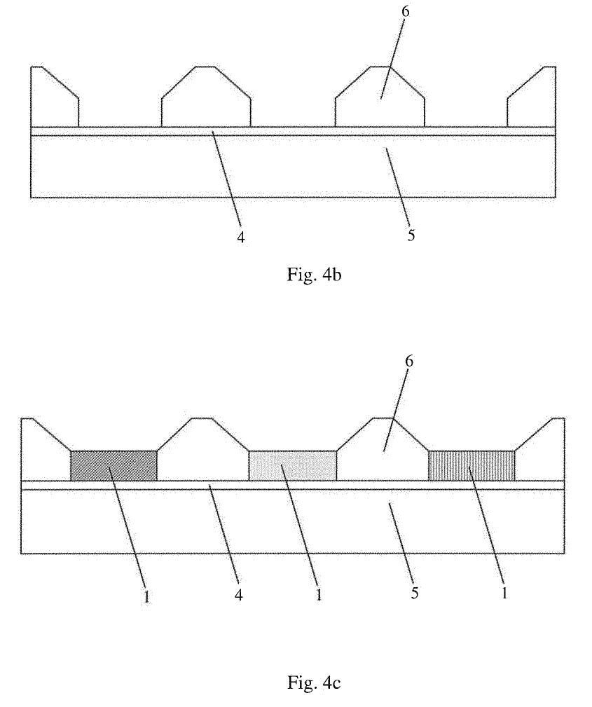

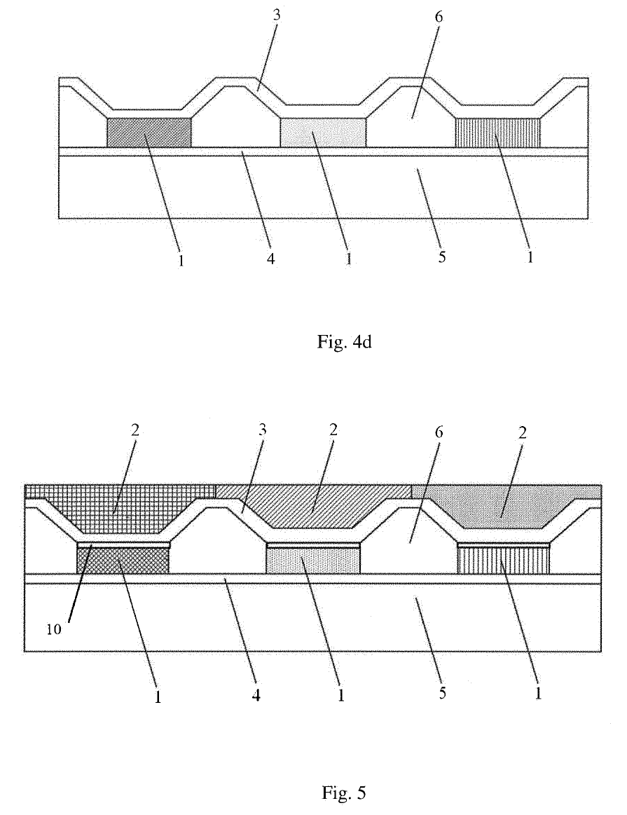

FIG. 4a is a schematic diagram of forming the first electrode in the third embodiment; as illustrated in FIG. 4a, the first electrode 4 is formed on the backplane 5. For example, the first electrode 4 may formed by way of PVD or CVD method.

Step 103: forming a pixel defining layer on the first electrode.

FIG. 4b is a schematic diagram of forming the pixel defining layer in the third embodiment; as illustrated in FIG. 4b, the pixel defining material layer is formed on the first electrode 4, and for example, the pixel defining layer 6 is formed by a patterning process with respect to the pixel defining material layer. For instance, the patterning process can comprise photoresist coating, photoresist exposure and developing, etching, and photoresist stripping.

Step 104: forming a light emitting layer on the first electrode after the step 103, the light emitting layer being arranged in the pixel defining layer.

FIG. 4c is a schematic diagram of forming the light emitting layer in the third embodiment; as illustrated in FIG. 4c, the emitting material layer is on the first electrode 4 after the step 103 finished, the light emitting layer 1 is formed by a patterning process with respect to the emitting material layer, the formed light emitting layer 1 is arranged in the pixel defining layer 6. Alternatively, in the case where a plurality of light emitting layers are provided, for example, the light emitting layers 1 comprise a red light emitting layer R, a green light emitting layer G, and a blue light emitting layer B, the red light emitting layer R, the green light emitting layer G and the blue light emitting layer B can be formed by a vapor deposition process with a mask plate in order.

Step 105: forming a second electrode on the light emitting layer and the pixel defining layer.

Step 106: forming an encapsulation layer on the second electrode.

FIG. 4d is a schematic diagram of forming the encapsulation layer in the third embodiment; as illustrated in FIG. 4d, the encapsulation layer 3 is formed on the light emitting layer 1 and the pixel defining layer 6. For example, the encapsulation layer 3 is formed of an inorganic insulation material, such as SiOx or SiOxNy, by way of CVD method.

Step 107: forming a light filter pattern on the encapsulation layer.

As illustrated in FIG. 1, the light filter pattern 2 can be formed on the encapsulation layer 3 by a vapor deposition process or a printing process.

The method of manufacturing the display panel provided by the present embodiment can use for manufacturing the display panel provided by above-mentioned embodiment 1.

The display panel manufactured according to the method of manufacturing the display panel provided by the present embodiment, the light filter pattern is located at the light-emitting side of the corresponding light emitting layer, and the light filter pattern has a specific transmission spectrum; the light filter pattern is used for filter out the light corresponding to the spectrum outside the specific transmission spectrum and transmit the light corresponding to the specific transmission spectrum; the light filter pattern can filter out part of light, thus the reflectivity of ambient light irradiated on the display panel is decreased and the contrast ratio of the display panel is increased.

The present application claims the priority of Chinese patent application No. 201610127607.5 filed on Mar. 7, 2016, the disclosure of which is incorporated herein by reference in its entirety.

1. A display panel, comprising: a light emitting layer and a light filter pattern corresponding to the light emitting layer, wherein each of the light emitting layers is configured to emit monochromatic light, and the light emitting layers comprises at least a first emitting layer and a second emitting layer, the monochromatic light emitted by the first emitting layer are different from the monochromatic light emitted by the second emitting layer;
the light filter pattern is located at a light-emitting side of the light emitting layer, and the light filter pattern has a specific transmission spectrum; and
the light filter pattern is configured for filtering out light corresponding to a spectrum outside the specific transmission spectrum and transmitting light corresponding to the specific transmission spectrum.

2. The display panel according to claim 1, wherein, an absolute value of difference between a peak value of the specific transmission spectrum of the light filter pattern and a peak value of an emission spectrum of the light emitting layer is no more than a first set value.

3. The display panel according to claim 2, wherein, the first set value is 5 nm.

4. The display panel according to claim 2, wherein, an absolute value of difference between an FWHM (full width at half maximum) value of the specific transmission spectrum of the light filter pattern and an FWHM value of the emission spectrum of the light emitting layer is no more than a second set value.

5. The display panel according to claim 4, wherein, the second set value is 40 nm.

6. The display panel according to claim 4, wherein, the difference between the peak value of the specific transmission spectrum of the light filter pattern and the peak value of the emission spectrum of the light emitting layer is zero, and the difference between the FWHM value of the specific transmission spectrum of the light filter pattern and the FWHM value of the emission spectrum of the light emitting layer is zero.

7. The display panel according to claim 1, further comprising an encapsulation layer, wherein, the encapsulation layer is arranged on the light emitting layer, and the light filter pattern is arranged on the encapsulation layer.

8. The display panel according to claim 1, further comprising a first electrode, wherein, the first electrode is arranged below the light emitting layer; and
the first electrode has reflectivity and is configured to reflect incident light.

9. The display panel according to claim 1, further comprising a pixel defining layer, wherein, the light emitting layer is arranged in the pixel defining layer, the pixel defining layer at both sides of the light emitting layer form a groove above the light emitting layer, and the light filter pattern corresponding to the light emitting layer is located in the groove.

10. The display panel according to claim 8, further comprising a second electrode, wherein, the second electrode is arranged on the light emitting layer.

11. A display device, comprising: the display panel according to claim 1.

12. A method of manufacturing a display panel, comprising:
forming a light emitting layer, wherein each of the light emitting layers is configured to emit monochromatic light, and the light emitting layers comprises at least a first emitting layer and a second emitting layer, the monochromatic light emitted by the first emitting layer are different from the monochromatic light emitted by the second emitting layer; and
forming a light filter pattern, wherein the light filter pattern is located at a light-emitting side of the light emitting layer, the light filter pattern has a specific transmission spectrum, and the light filter pattern is configured for filtering out light corresponding to a spectrum outside the specific transmission spectrum and transmitting the light corresponding to the specific transmission spectrum.

13. The method according to claim 12, wherein, the light filter pattern is formed through a vapor deposition process or a printing process.

14. The method according to claim 12, after forming the light emitting layer, further comprising:
forming an encapsulation layer, wherein, the light filter pattern is arranged on the encapsulation layer.

15. The method according to claim 12, before forming the light emitting layer, further comprising:
forming a pixel defining layer, wherein, the light emitting layer is arranged in the pixel defining layer, the pixel defining layer at both sides of the light emitting layer form a groove above the light emitting layer, and the light filter pattern corresponding to the light emitting layer is located in the groove.

16. The method according to claim 12, further comprising:
providing a backplane, wherein, the light emitting layer is formed on the backplane.

17. The method according to claim 16, further comprising:
forming a first electrode on the backplane, wherein, the light emitting layer is formed on the first electrode, and the first electrode has reflectivity and is configured to reflect the received light.

18. The method according to claim 17, further comprising:
forming a second electrode on the light emitting layer.

19. A display panel, comprising: a light emitting layer and a light filter pattern corresponding to the light emitting layer,
wherein the light filter pattern is located at a light-emitting side of the light emitting layer, and the light filter pattern has a specific transmission spectrum;
the light filter pattern is configured for filtering out light corresponding to a spectrum outside the specific transmission spectrum and transmitting light corresponding to the specific transmission spectrum;
an absolute value of difference between a peak value of the specific transmission spectrum of the light filter pattern and a peak value of an emission spectrum of the light emitting layer is no more than a first set value, and the first set value is 5 nm.
